(19) United States
(12) Patent Application Publication
(10) Pub. No.: US 2008/0105926 A1
(43) Pub. Date: May 8, 2008

(54) THIN FILM TRANSISTOR AND FABRICATION METHOD THEREOF

(75) Inventors: Chin-Chuan Lai, Taoyuan County (TW); Hsian-Kun Chiu, Taipei City (TW); Yi-Pen Lin, Taoyuan County (TW); Shu-Chen Yang, Tainan County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(73) Assignee: CHUNGHWA PICTURE TUBES, LTD., Taipei (TW)

(21) Appl. No.: 11/738,524

(22) Filed: Apr. 23, 2007

(30) Foreign Application Priority Data
Nov. 6, 2006 (TW) 95140945

(51) Int. Cl. H01L 29/786; H01L 21/336

(52) U.S. Cl. 257/347; 438/151; 257/E29.273

(57) ABSTRACT

A thin film transistor and a fabrication method thereof are provided. First, a gate is formed on a substrate. Next, a gate insulating layer is formed to cover the gate and then a channel layer is formed on a portion of the gate insulating layer above the gate. Afterwards, a source and a drain are formed on the channel layer. The method of forming the gate includes forming a copper alloy layer containing nitrogen and a copper layer sequentially and then removing a portion of the copper alloy layer containing nitrogen and the copper layer. The source and the drain could be formed by the same fabrication method.

### CROSS-REFERENCE TO RELATED APPLICATION

This application claims the priority benefit of Taiwan application serial no. 95140945, filed on Nov. 6, 2006. All disclosure of the Taiwan application is incorporated herein by reference.

### BACKGROUND OF THE INVENTION

1. Field of the Invention

The present invention relates to an active device and a fabrication method thereof, and more particularly to a thin film transistor and a fabrication method thereof.

2. Description of Related Art

Metals such as Mo, Ta, Cr, W and an alloy thereof are generally used as the interconnects in common liquid crystal display panels, in which Al is the most commonly used. However, compared with Al, the electromigration of copper is lower and copper has low resistivity, so that copper has become an attractive subject for many researchers in this area in recent years.

However, it is difficult to use copper as the interconnect since the thermal stability of copper is poor. For example, in the fabrication of thin film transistors, the copper used as a gate is easily melted under high temperature, and then the copper atom penetrates through the interface of copper and silicon or the interface of copper and silicon dioxide. The diffusion of copper will change the electrical property of the thin film transistor, or reduce the reliability of the thin film transistor. Further, since the adhesion between copper and silicon is poor, the peeling of copper frequently occurs. Therefore, the yield of products cannot be improved.

### SUMMARY OF THE INVENTION

The present invention provides a method of fabricating a thin film transistor, so as to alleviate ion diffusion phenomenon.

The present invention provides a thin film transistor, which has a higher reliability.

The present invention provides a method of fabricating a thin film transistor. First, a first copper alloy layer containing nitrogen and a first copper layer are sequentially formed on a substrate. Next, a portion of the first copper alloy layer containing nitrogen and the first copper layer are removed, so as to form a gate on the substrate. Then, a gate insulating layer is formed to cover gate, and then a channel layer is formed on a portion of the gate insulating layer above the gate. Thereafter, a source and a drain are formed on the channel layer, wherein the method of forming the source and the drain includes forming a second copper alloy layer containing nitrogen and a second copper layer sequentially above the substrate. Afterwards, a portion of the second copper alloy layer containing nitrogen and the second copper layer are removed.

In an embodiment of the present invention, the process of forming the first copper alloy layer containing nitrogen is, for example, physical vapor deposition. A sputtering target or an evaporation source used in the physical vapor deposition process includes copper and one selected from a group consisting of Mo, W, Ti, Cr, Ta, In, Sn, Al, and Mn.

In an embodiment of the present invention, the process of forming the second copper alloy layer containing nitrogen is, for example, physical vapor deposition process. A sputtering target or an evaporation source used in the physical vapor deposition process includes copper and one selected from a group consisting of Mo, W, Ti, Cr, Ta, In, Sn, Al, and Mn.

In an embodiment of the present invention, the gas used in the physical vapor deposition process includes a nitrogen-containing gas, and a flow ratio of the nitrogen-containing gas to the whole gas is, for example, from 5% to 50%.

In an embodiment of the present invention, the nitrogen-containing gas is, for example, ammonia gas or nitrogen gas.

The present invention further provides a thin film transistor, which includes a gate, a gate insulating layer, a channel layer, a source, and a drain. The gate is disposed on the substrate, and includes a first copper alloy layer containing nitrogen and a first copper layer. The first copper layer is disposed on the first copper alloy layer containing nitrogen. The gate insulating layer covers the gate, and the channel layer is disposed on a portion of the gate insulating layer above the gate. Further, the source and the drain are disposed on the channel layer, wherein each of the source and the drain includes a second copper alloy layer containing nitrogen and a second copper layer. The second copper alloy layer containing nitrogen is disposed on the channel layer, and the second copper layer is disposed on the second copper alloy layer containing nitrogen.

In an embodiment of the present invention, the first copper alloy layer containing nitrogen includes a nitride alloy of copper and one selected from a group consisting of Mo, W, Ti, Cr, Ta, In, Sn, Al, and Mn.

In an embodiment of the present invention, the second copper alloy layer containing nitrogen includes a nitride alloy of copper and one selected from a group consisting of Mo, W, Ti, Cr, Ta, In, Sn, Al, and Mn.

In an embodiment of the present invention, the thickness of the first copper alloy layer containing nitrogen is from 200 angstrom to 500 angstrom.

In an embodiment of the present invention, the thickness of the second copper alloy layer containing nitrogen is from 200 angstrom to 500 angstrom.

In an embodiment of the present invention, the thickness of the first copper layer is from 1500 angstrom to 4000 angstrom.

In an embodiment of the present invention, the thickness of the second copper layer is from 1500 angstrom to 4000 angstrom.

In an embodiment of the present invention, the thickness ratio of the first copper layer to the first copper alloy layer containing nitrogen is from 5 to 15.

In an embodiment of the present invention, the thickness ratio of the second copper layer to the second copper alloy layer containing nitrogen is from 5 to 15.

In an embodiment of the present invention, the total thickness of the first copper layer and the first copper alloy layer containing nitrogen is from 2000 angstrom to 4000 angstrom.

In an embodiment of the present invention, the total thickness of the second copper layer and the second copper alloy layer containing nitrogen is from 2000 angstrom to 4000 angstrom.

Since the thin film transistor of the present invention adopts the second copper alloy layer containing nitrogen as a barrier layer, the ion diffusion phenomenon between the second copper layer and the channel layer can be alleviated. Furthermore, the first copper alloy layer containing nitrogen can also be used as an adhesion layer, so as to enhance the bonding strength between the first copper layer and the substrate, thereby reducing the possibility of the occurrence of copper layer stripping or copper peeling.

In order to make the aforementioned and other objects, features and advantages of the present invention comprehensible, preferred embodiments accompanied with figures are described in detail below.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A to 1D are top views of the processes of fabricating a thin film transistor according to an embodiment of the present invention.

FIGS. 2A to 2D are cross-sectional views taken along the cross-sectional line I-I in FIGS. 1A to 1D, respectively.

### DESCRIPTION OF EMBODIMENTS

In view of the above defects in the conventional art, the present invention provides a copper alloy layer containing nitrogen/copper layer bilayered structure, which is used as a gate, source, and drain of a thin film transistor, so as to alleviate the copper diffusion phenomenon and enhance the adhesion between the copper and the silicon.

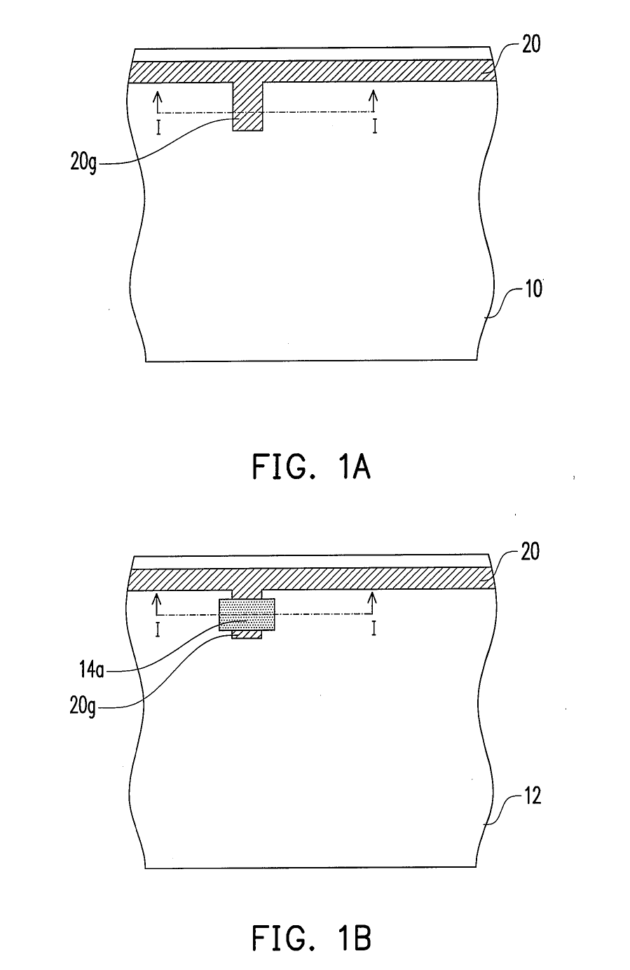

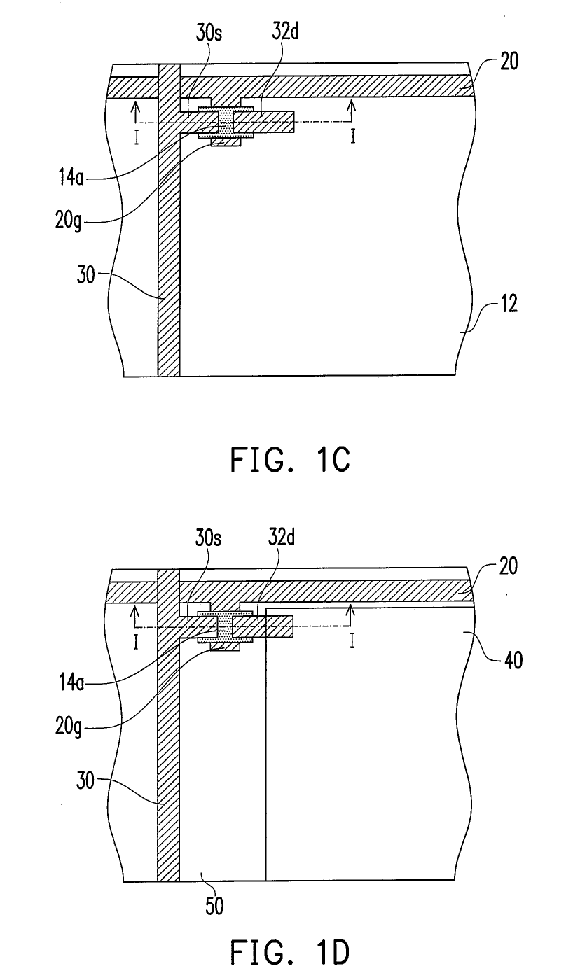

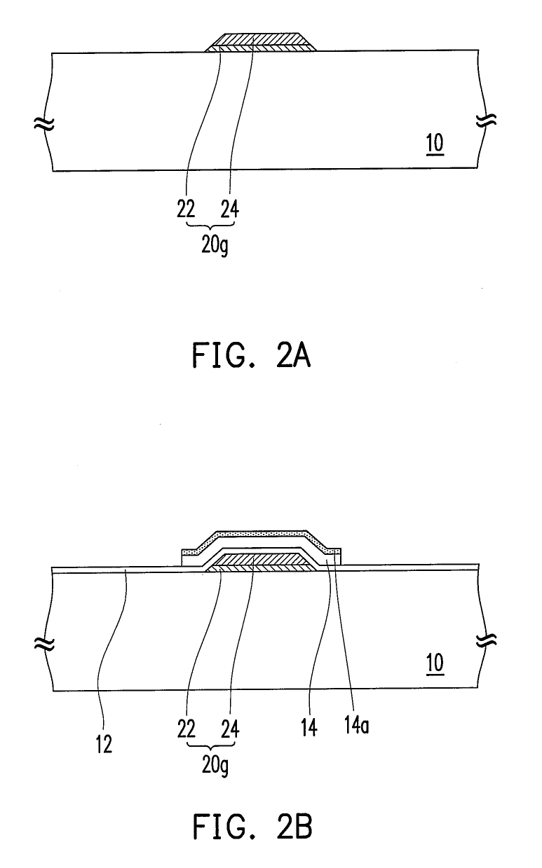

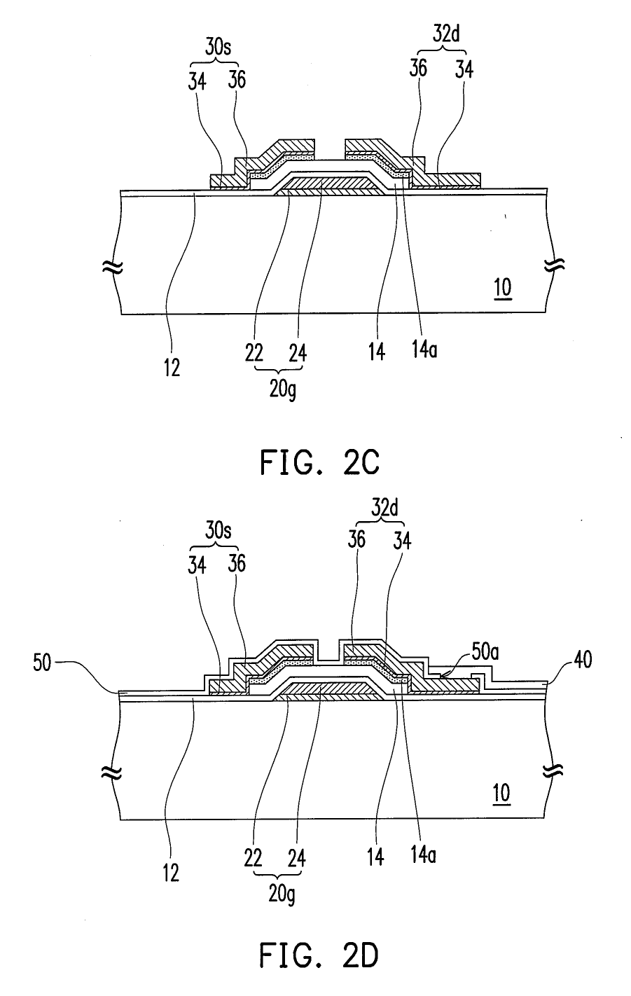

FIGS. 1A to 1D are top views of the processes of fabricating a thin film transistor according to an embodiment of the present invention. FIGS. 2A to 2D are cross-sectional views taken along the cross-sectional line I-I in FIGS. 1A to 1D, respectively. The scope depicted in FIGS. 1A to 1D is one pixel structure of a thin film transistor (TFT) array substrate. The thin film transistor of the present invention is illustrated below with reference to FIG. 1D and FIG. 2D, and then the fabrication method is illustrated.

Regarding to FIG. 1D and FIG. 2D together, the thin film transistor of the present invention includes a gate 20g, a gate insulating layer 12, a channel layer 14, a source 30s, and a drain 32d, wherein the gate 20g is disposed on the substrate 10. The gate 20g includes a first copper alloy layer containing nitrogen 22 and a first copper layer 24, wherein the first copper layer 24 is disposed on the first copper alloy layer containing nitrogen 22. In this embodiment, the first copper alloy layer containing nitrogen 22 includes a nitride alloy of copper and one selected from a group consisting of Mo, W, Ti, Cr, Ta, In, Sn, Al, and Mn, such as Cu—Mo nitride alloy and Cu—Mo—W nitride alloy. Furthermore, the gate 20g is a portion of a scan line 20, so the first copper alloy layer containing nitrogen 22 and the first copper layer 24 can be used as wires. The first copper alloy layer containing nitrogen 22 is used as a barrier layer, so as to alleviate the ion diffusion phenomenon between the first copper layer 24 and the substrate 10. Furthermore, the first copper alloy layer containing nitrogen 22 is used as the adhesion layer to reduce the possibility of the occurrence of the first copper layer 24 from stripping off from the surface of the substrate 10.

Particularly, the thickness of the first copper alloy layer containing nitrogen 22 is from 200 angstrom to 500 angstrom, and the thickness of the first copper layer 24 is from 1500 angstrom to 4000 angstrom. Or, the thickness ratio of the first copper layer 24 to the first copper alloy layer containing nitrogen 22 is from 5 to 15. Or, the total thickness of the first copper layer 24 and the first copper alloy layer containing nitrogen 22 is from 2000 angstrom to 4000 angstrom.

The gate insulating layer 12 covers the gate 20g. Generally speaking, the gate insulating layer 12 covers the entire substrate 10 and the gate 20g. The material of the gate insulating layer 12 is, for example, silicon oxide or silicon nitride. Further, the channel layer 14 is disposed on a portion of the gate insulating layer 12 above the gate 20g, and the material of the channel layer 14 is, for example, amorphous silicon or polysilicon.

The source 30s and the drain 32d are disposed on the channel layer 14. As shown in FIG. 1D, in this embodiment, the source 30s is a portion of one data line 30. An ohmic contact layer 14a is also disposed between the source 30s and the channel layer 14, and between the drain 32d and the channel layer 14. The materials of the ohmic contact layer 14a and the channel layer 14 both are amorphous silicon or poly-silicon, and the ohmic contact layer 14a further include dopant. The dopant generally is N-type dopant. In other words, the thin film transistor generally is N-type field effect transistor.

Furthermore, in this embodiment, the source 30s and the drain 32d also include a second copper alloy layer containing nitrogen 34 and a second copper layer 36. The second copper alloy layer containing nitrogen 34 is disposed on the channel layer 14, and the second copper layer 36 is disposed on the second copper alloy layer containing nitrogen 34. The second copper alloy layer containing nitrogen 34 also includes a nitride alloy of copper and one selected from a group consisting of Mo, W, Ti, Cr, Ta, In, Sn, Al, and Mn. The second copper alloy layer containing nitrogen 34 is used as a barrier layer for alleviating the ion diffusion phenomenon between the second copper layer 36 and the channel layer 14.

Particularly, the thickness of the second copper alloy layer containing nitrogen 34 is from 200 angstrom to 500 angstrom, and the thickness of the second copper layer 36 is from 1500 angstrom to 4000 angstrom. Or, the thickness ratio of the second copper layer 36 to the second copper alloy layer containing nitrogen 34 is from 5 to 15. Or, the total thickness of the second copper layer 36 and the second copper alloy layer containing nitrogen 34 is from 2000 angstrom to 4000 angstrom.

In addition, in FIG. 1D, if the thin film transistor is applied in one pixel structure of a TFT array substrate, the pixel structure further includes one pixel electrode 40 and a passivation layer 50, wherein the passivation layer 50 has a contact hole 50a, and the pixel electrode 40 is electrically connected to the drain 32d via the contact hole 50a.

Since the thin film transistor of the present invention adopts the copper alloy layer containing nitrogen as the barrier layer, the ion diffusion phenomenon between the copper layer of the gate and the substrate is alleviated, and the ion diffusion phenomenon between the copper layer of the source and drain and the ohmic contact layer and the channel layer is also alleviated. Furthermore, the copper alloy layer containing nitrogen also can be used as an adhesion layer to reduce the possibility of the occurrence of the stripping of copper layer and the peeling of copper. Thus, the thin film transistor of the present invention has relatively high yield and reliability.

The method of fabricating the above thin film transistor is illustrated below with reference to FIGS. 1A to 1D and FIG. 2A to 2D. It should be noted that the fabrication method of the above thin film transistor is not limited to this.

Regarding to FIGS. 1A and 2A together, a substrate 10 is first provided. Next, one first copper alloy material layer containing nitrogen (not shown) and one first copper material layer (not shown) are sequentially formed on the substrate 10. In this embodiment, the process of forming the first copper alloy material layer containing nitrogen is a physical vapor deposition process including sputtering deposition and evaporation. A sputtering target or evaporation source used in the physical vapor deposition process includes copper and any one selected from a group consisting of Mo, W, Ti, Cr, Ta, In, Sn, Al, and Mn, such as Cu—Mo alloy and Cu—Mo—W alloy. In the sputtering target or the evaporation source, the molar ratio of copper is, for example, from 90% to 99.9%.

Furthermore, the gas used in the physical vapor deposition process includes a nitrogen-containing gas, and the flow ratio of the nitrogen-containing gas to the whole gas is, for example, from 5% to 50%. In addition, the nitrogen-containing gas is, for example, ammonia gas or nitrogen gas. In the other aspect, the process of forming the first copper material layer is also the physical vapor deposition process. Then, a portion of the first copper alloy material layer containing nitrogen and a portion of the first copper material layer are removed, so as to form a first copper alloy layer containing nitrogen 22 and a first copper layer 24, thereby constituting a gate 20g. In addition, the portion of the first copper alloy material layer containing nitrogen and the portion of the first copper material layer are removed through a lithography process and then a wet etching process. In this embodiment, as the gate 20g is formed, the scan line 20 is formed at the same time.

Then, regarding to FIG. 1B and FIG. 2B together, a gate insulating layer 12 is formed to cover the gate 20g. The material of the gate insulating layer 12 is, for example, silicon oxide or silicon nitride, and the process of forming the gate insulating layer 12 is, for example, a plasma enhanced chemical vapor deposition (PECVD) process. Then, a channel layer 14 is formed on a portion of the gate insulating layer 12 above the gate 20g. The material of the channel layer 14 is, for example, amorphous silicon or polysilicon.

The method of forming the channel layer 14 of the amorphous silicon includes, for example, forming an amorphous silicon layer through the chemical vapor deposition process, and then performing the lithography process and the etching process. The method of forming the channel layer 14 of polysilicon is similar to that of the channel layer 14 of the amorphous silicon, except that before the lithography process, the amorphous silicon layer is annealed. Furthermore, in this embodiment, after the above chemical vapor deposition process, or after the above chemical vapor deposition or the annealing process, a doping process is further performed, so as to form an ohmic contact layer 14a on the surface of the channel layer 14.

Then, regarding to FIG. 1C and FIG. 2C together, the source 30s and the drain 32d are formed on the channel layer 14. The method of forming the source 30s and the drain 32d includes, for example, forming a second copper alloy material layer containing nitrogen (not shown) and a second copper material layer (not shown) sequentially above the substrate 10. In this embodiment, the method of forming the second copper alloy material layer containing nitrogen is the physical vapor deposition process including sputtering deposition and evaporation. The sputtering target or the evaporation source used in the physical vapor deposition process includes copper and one selected from a group consisting of Mo, W, Ti, Cr, Ta, In, Sn, Al, and Mn, such as Cu—Mo alloy and Cu—Mo—W alloy.

In the sputtering target or the evaporation source, the molar ratio of copper is from, for example, 90% to 99.9%. Furthermore, the gas used in the physical vapor deposition process includes a nitrogen-containing gas, and the flow ratio of the nitrogen-containing gas to the whole gas is, for example, from 5% to 50%. In addition, the nitrogen-containing gas is, for example, ammonia gas or nitrogen gas. In the other aspect, the method of forming the second copper material layer is, for example, physical vapor deposition process. Then, a portion of the second copper alloy material layer containing nitrogen and a portion of the second copper material layer are removed through the lithography process and then the wet etching process, so as to form a source 30s and a drain 32d. In this embodiment, as the source 30s and the drain 32d are formed, the data line 30 is formed at the same time. Thus, the thin film transistor according to a first embodiment of the present invention is completed.

Then, regarding to FIG. 1D and FIG. 2D together, when the thin film transistor is applied in the TFT array substrate, the subsequent process further includes forming a passivation layer 50 and a pixel electrode 40 sequentially on the substrate 10, wherein the passivation layer 50 has a contact hole 50a which exposes a portion of the drain 32d, and the pixel electrode 40 is electrically connected to the drain 32d via the contact hole 50a. The material and the forming method of the passivation layer 50 and the pixel electrode 40 are known to those of ordinary skill in the art, and the details will not be described herein again.

To sum up, the fabrication method disclosed in the present invention includes forming a copper alloy layer containing nitrogen and a copper layer in one step of the physical vapor deposition process, such that the ion diffusion phenomenon and the copper peeling of the copper layer of the gate and the copper layer of the source and the drain will not easily occur, thereby forming the thin film transistor with high yield and high reliability. Furthermore, it is not difficult to fabricate the copper alloy layer containing nitrogen. Thus, the present invention can be achieved by the currently used equipments and techniques.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method of fabricating a thin film transistor, comprising:
forming a first copper alloy layer containing nitrogen and a first copper layer sequentially on a substrate;
removing a portion of the first copper alloy layer containing nitrogen and the first copper layer, so as to form a gate on the substrate;
forming a gate insulating layer to cover the gate;
forming a channel layer on a portion of the gate insulating layer above the gate;
forming a source and a drain on the channel layer, wherein the method of forming the source and the drain comprises:
forming a second copper alloy layer containing nitrogen and a second copper layer sequentially above the substrate; and
removing a portion of the second copper alloy layer containing nitrogen and the second copper layer.

2. The method of fabricating the thin film transistor as claimed in claim 1, wherein the process of forming the second copper alloy layer containing nitrogen is a physical vapor deposition process, and a sputtering target or an evaporation source used in the physical vapor deposition process comprises copper and one selected from a group consisting of Mo, W, Ti, Cr, Ta, In, Sn, Al, and Mn.

3. The method of fabricating the thin film transistor as claimed in claim 2, wherein the gas used in the physical vapor deposition process comprises a nitrogen-containing gas, and a flow ratio of the nitrogen-containing gas to the whole gas is from 5% to 50%.

4. The method of fabricating the thin film transistor as claimed in claim 3, wherein the nitrogen-containing gas comprises ammonia gas or nitrogen gas.

5. The method of fabricating the thin film transistor as claimed in claim 1, wherein the process of forming the first copper alloy layer containing nitrogen is a physical vapor deposition process, and a sputtering target or an evaporation source used in the physical vapor deposition process comprises copper and one selected from a group consisting of Mo, W, Ti, Cr, Ta, In, Sn, Al, and Mn.

6. The method of fabricating the thin film transistor as claimed in claim 5, wherein the gas used in the physical vapor deposition process comprises a nitrogen-containing gas, and a flow ratio of the nitrogen-containing gas to the whole gas is from 5% to 50%.

7. The method of fabricating the thin film transistor as claimed in claim 6, wherein the nitrogen-containing gas comprises ammonia gas or nitrogen gas.

8. A thin film transistor, comprising:
a gate, disposed on a substrate, comprising:
a first copper alloy layer containing nitrogen;
a first copper layer, disposed on the first copper alloy layer containing nitrogen;
a gate insulating layer, covering the gate;
a channel layer, disposed on a portion of the gate insulating layer above the gate;
a source and a drain, disposed on the channel layer, wherein each of the source and the drain comprises:
a second copper alloy layer containing nitrogen, disposed on the channel layer; and
a second copper layer, disposed on the second copper alloy layer containing nitrogen.

9. The thin film transistor as claimed in claim 8, wherein the second copper alloy layer containing nitrogen comprises a nitride alloy of copper and one selected from a group consisting of Mo, W, Ti, Cr, Ta, In, Sn, Al, and Mn.

10. The thin film transistor as claimed in claim 8, wherein the first copper alloy layer containing nitrogen comprises a nitride alloy of copper and one selected from a group consisting of Mo, W, Ti, Cr, Ta, In, Sn, Al, and Mn.

11. The thin film transistor as claimed in claim 8, wherein the thickness of the first copper alloy layer containing nitrogen is from 200 angstrom to 500 angstrom.

12. The thin film transistor as claimed in claim 8, wherein the thickness of the second copper alloy layer containing nitrogen is from 200 angstrom to 500 angstrom.

13. The thin film transistor as claimed in claim 8, wherein the thickness of the first copper layer is from 1500 angstrom to 4000 angstrom.

14. The thin film transistor as claimed in claim 8, wherein the thickness of the second copper layer is from 1500 angstrom to 4000 angstrom.

15. The thin film transistor as claimed in claim 8, wherein the thickness ratio of the first copper layer to the first copper alloy layer containing nitrogen is from 5 to 15.

16. The thin film transistor as claimed in claim 8, wherein the thickness ratio of the second copper layer to the second copper alloy layer containing nitrogen is from 5 to 15.

17. The thin film transistor as claimed in claim 8, wherein the total thickness of the first copper layer and the first copper alloy layer containing nitrogen is from 2000 angstrom to 4000 angstrom.

18. The thin film transistor as claimed in claim 8, wherein the total thickness of the second copper layer and the second copper alloy layer containing nitrogen is from 2000 angstrom to 4000 angstrom.
